(19) United States
(12) Patent Application Publication
(10) Pub. No.: US 2016/0247960 A1
(43) Pub. Date: Aug. 25, 2016

(54) Method for Fabricating a Photovoltaic Cell

(71) Applicant: COMMISSARIAT À L'ENERGIE ATOMIQUE ET AUX ENERGIES ALTERNATIVES, Paris (FR)

(72) Inventor: Armand BETTINELLI, Coublevie (FR)

(73) Assignee: COMMISSARIAT À L'ENERGIE ATOMIQUE ET AUX ENERGIES ALTERNATIVES, Paris (FR)

(21) Appl. No.: 15/028,078

(22) PCT Filed: Oct. 14, 2014
(86) PCT No.: PCT/FR2014/052614

§ 371 Date: Apr. 8, 2016

(30) Foreign Application Priority Data
Oct. 15, 2013 (FR) 1302390

(51) Int. Cl. H01L 31/18; H01L 31/0747; H01L 31/20; H01L 31/0224

(52) U.S. Cl. CPC H01L 31/1884; H01L 31/022433; H01L 31/022475; H01L 31/0747; H01L 31/208; H01L 31/202

(57) ABSTRACT

A method for producing a photovoltaic cell including the following successive steps: i) providing a substrate including a p/n photovoltaic junction, successively covered by a transparent conductive oxide layer, a first layer made from electrically insulating material and a second layer made from metallic material; ii) performing localised heat treatment by laser irradiation under conditions enabling the electrically insulating material and the metallic material to be made to react locally to form a seed layer, made from a metal-charged glassy compound, the seed layer being electrically connected to the p/n junction by way of the transparent conductive oxide layer; iii) performing removal of the second layer of metallic material; iv) performing formation of an electric contact on the seed layer by electrochemical deposition.

### BACKGROUND OAF THE INVENTION

The invention relates to a method for fabricating a photovoltaic cell and to a photovoltaic cell obtained in this way.

### STATE OF THE ART

A photovoltaic cell can be formed by a multilayer stack, more often than not comprising semiconductor materials and enabling the received photons to be converted directly into an electric signal. Such a photovoltaic cell can for example be a homojunction or a heterojunction photovoltaic cell. These cells are often made from silicon.

One of the steps involved in fabrication of photovoltaic cells is the metallization step. This metallization takes place towards the end of the photovoltaic cell fabrication method and consists in depositing metal contacts, generally in the form of combs or gates, on at least one of the surfaces of the cell. These metal contacts are designed to collect the current and to interconnect the cells to one another.

To make the electric contacts, metal lines are in general deposited by screen printing. The metal lines are for example made from a silver base. This technique enables metal contacts to be achieved quickly. It does however present a certain number of limitations such as for example a higher resistivity of the electric contacts and a large width of the lines. The width of the lines is generally about 70 μm to 120 μm, which causes a consequent shadowing effect on the surface of the cell thereby reducing its efficiency.

In addition, after deposition of the silver paste on the photovoltaic cell an anneal is necessary to enable both contact connection and densification of the paste.

For homojunction cells, the anneals are performed at high temperature, about 800° C. The contact connection takes place when the silver passes through the anti-reflective layer of the cell and comes into contact with the emitting, region of said cell.

For heterojunction cells, the anneals are performed at a lower temperature, about 200° C., as the amorphous layers, present in heterojunction cells, have a poor temperature withstand. They recrystallize partially at temperatures above 200° C., thereby losing their passivation properties. The contact connection is made directly in the case of heterojunction cells on the transparent conductive oxide layer.

The resistivity of a silver paste annealed at high temperature is however almost twice as great as the resistivity of volume silver and the resistivity of a silver paste densified at low temperature is 4 to 5 times higher than the resistivity of volume silver. The resistivity of the electric contacts obtained with this technique is therefore much higher than that of the volume metal.

Increasing the annealing temperature would enable the resistivity of the metal contacts to be reduced but this increase would result in partial crystallisation of the amorphous layers present in the heterojunction cells.

The method for fabricating electric contacts therefore consists in finding a trade-off between the quality of the electric contacts, and in particular their electric resistivity properties, and the quality of the amorphous layers, the quality of one often being achieved to the detriment of the other.

Another technique used to form electric contacts is photolithography associated with electrolytic growth. Photolithography, derived from the techniques used in the microelectronics field, enables very narrow patterns, of about 10 μm or 20 μm, to be produced on photovoltaic cells at ambient temperature, by means of deposition of a photoresist. The shadowing is thus limited and the efficiencies of the photovoltaic cells are improved. However, this technique is lengthy to implement and presents a very high cost, which is not compatible with production of photovoltaic cells.

Furthermore, the major drawback of galvanic recharges resides in adhesion of the depositions on the substrate.

In the case of homojunction cells, a nickel sub-layer is used to form a nickel silicide thereby enabling a better adhesion of the electrolytic deposition.

However, the formation of nickel silicides generally leads to the occurrence of micro-short-circuits.

In the case of heterojunction cells, the adhesion of the galvanic depositions on the transparent conductive oxide layer is always insufficient.

The industrial difficulty is therefore to achieve metallic contacts, for photovoltaic cells, that are relatively narrow, present a low resistivity and a good adhesion on the support, with a relatively high production rate and, in the case of heterojunction cells, without crystallizing the amorphous layers.

### OBJECT OF THE INVENTION

The object of the invention is to remedy the drawbacks of the, prior art, and in particular to propose a method for fabricating a photovoltaic cell enabling electric contacts to be made, presenting a low resistivity, while at the same time preserving the underlying layers made from semiconductor material.

This object tends to be achieved by the appended claims,

### BRIEF DESCRIPTION O THE DRAWINGS

Other advantages and features will become more clearly apparent, from the following description of particular embodiments of the invention given for non-restrictive example purposes only and represented in the appended drawings, in which:

FIGS. 1 to 4 represent different steps of fabrication of a photovoltaic cell according to a first embodiment, in schematic manner and in cross-section,

FIGS. 5 and 6 represent a photovoltaic cell according to a second and third embodiment, in schematic manner and in cross-section.

### DESCRIPTION OF PREFERRED EMBODIMENT OF THE INVENTION

The method for fabricating a photovoltaic cell comprises the following successive steps:
i) providing a substrate 1 comprising a pin photovoltaic junction, successively covered by a first layer made from electrically insulating material 2 and a second layer 3 made from metallic material,
ii) performing localised heat treatment by laser irradiation under conditions enabling the electrically insulating material and the metallic material to be made to react locally to form a seed layer 4, made from a metal-charged glassy compound, said seed layer 4 being electrically connected to the pin junction,
iii) performing removal of the second layer 3 of metallic material.
iv) performing formation of an electric contact 5 on the seed layer 4 by electrochemical deposition.

According to a preferred embodiment, the substrate comprises a transparent conductive oxide layer 6, placed between the pin photovoltaic junction and the first electrically insulating material layer 2. This is more particularly the case for heterojunction cells.

The seed layer 4 formed in step ii), i.e. when the localised heat treatment by laser irradiation is performed, is then electrically connected to the p/n junction by means of the transparent conductive oxide layer 6.

This transparent conductive oxide layer 6 enables a good, lateral conductivity to be had and thermally protects the semiconductor material layers forming the substrate when formation of the seed layer 4 takes place. The heat input is thus generated down to the transparent conductive oxide layer 6.

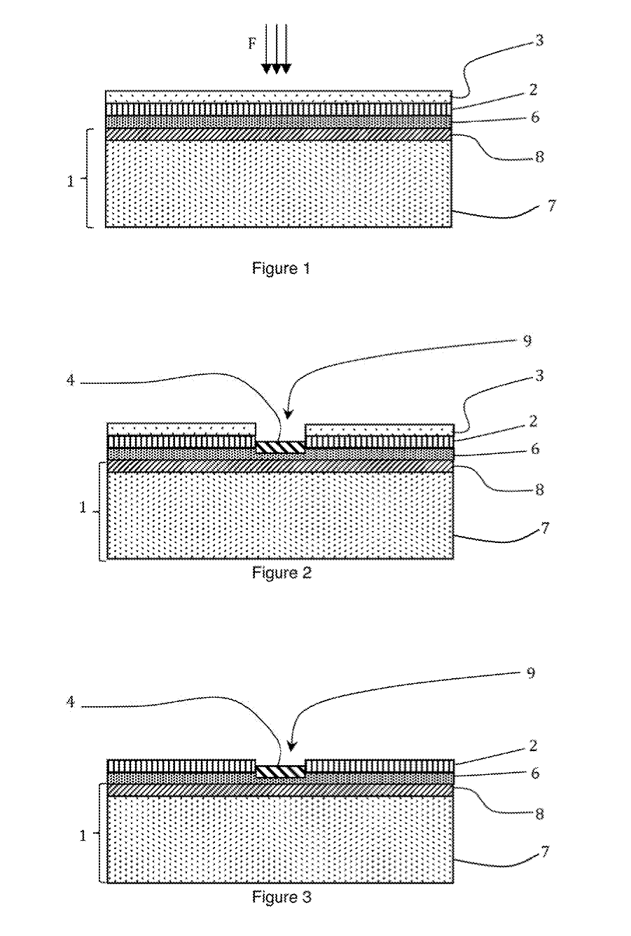

In step ii), the laser beam is applied from a source (not shown in FIG. 1) located above the photovoltaic cell. The laser beam is applied selectively to the place where the seed layer 4 is to be formed (arrows F in FIG. 1). The use of a laser beam advantageously enables a homogeneous but controlled heat input to be obtained notably in space and time.

The laser irradiation is performed under conditions (fluence, pulse duration) such that the heat input created by the localised application of the laser beam at the level of the second layer 3 made from metallic material, also called metallic layer 3, is sufficiently high to make said metallic layer 3 melt locally and cause at least softening, or even melting, of the first electrically insulating material layer 2, and possibly of a part of the transparent conductive oxide layer 6. This step enables an electrically conducting seed layer 4 to be formed.

According to a preferred embodiment, the laser irradiation is performed so as to cause softening rather than melting of the electrically insulating layer 2, thereby limiting the reaction with the transparent conductive oxide layer 6.

The heat treatment temperature, i.e. the temperature applied to the metallic layer 3 during application of the laser beam, is advantageously higher than or equal to the temperature at which melting of the metallic layer 3 takes place, and preferably higher than 900° C.

When the laser irradiation is performed, the material forming the seed layer 4 is created. The seed layer 4 is advantageously formed by the electrically insulating material of the first layer 2 and by the metallic material of the second layer 3.

The material of the seed layer 4 is in the form of a glassy compound, in particular a softened glass, charged with metal such as silver, It is for example of the type of glasses which form when baking of silver pastes called “high temperature” pastes used in screen printing is performed. These pastes are composed of a silver powder and a glass frit dispersed in an organic binder. What is meant by frit is a crushed glass powder which softens or melts when baked to form a glassy compound in which a part of the silver is dissolved to form an Ag-doped SiO₂ glass.

After laser irradiation and during cooling, a thin layer of this charged glass, with a thickness of a few tens of nanometres, forms the interface between the first layer of electrically insulating material 2 and the second layer 3 of metallic material. Silver crystallites can form enhancing the electric contact. This layer improves the adhesion of the metallizations, i.e. of the electric contacts.

Advantageously, and as represented in FIGS. 2 to 6, the seed layer 4 made from glassy material partially reacts chemically with the conducting transparent oxide 6 and/or mechanically, which enables the contact connection between the seed layer 4 and the oxide layer 6 to be made and the seed layer 4 to be electrically connected with the pin junction of the substrate 1.

According to a first embodiment, bonding of the seed layer 4 in glassy state, with the transparent conductive oxide layer 6 is achieved by chemical means, efficiently securing the two layers to one another. The material of the seed layer 4 is then a mixture of the materials of the metallic layer 3, of the insulating layer 2 and of the transparent conductive oxide layer 6.

According to another embodiment, when melting of the insulating layer 2 and metallic layer 3 takes place, the glassy material penetrates into the pores of the transparent conductive oxide layer 6 up to the grain boundary, enabling a strong mechanical bonding of the seed layer 4 in the oxide layer 6 to be obtained,

Diffusion and/or formation of the glassy material, composed of the materials of the metallic layer 3 and of the insulating layer 2, lead to formation of a via 9 passing through both the metallic layer 3 and at least a part of the insulating layer 2, as represented in FIG. 2.

The seed layer 4 is thus formed in the bottom of the via 9, the side walls of the via 9 being formed by the thickness of the insulating layer 2 and of the layer 3 that remained unmolten before removal of the latter. The via 9 is advantageously in the form of a groove, The electric contact 5 formed on the seed layer 4 will then be in the form of a line,

The width of the groove, and therefore of the via, corresponds approximately to the size of the laser beam. For example, by using a laser beam generating a focused spot of 15-20 μm, a seed layer 4 with a width of about 25 μm will be achieved.

As represented in FIGS. 2 to 4, after the formation step of the seed layer 4, the method comprises:
removal of the metallic layer 3 that remained un often to form the seed layer 4,
deposition of an electric contact 5 on the electrically conducting seed layer 4,

Preferentially, the metallic layer 3 is removed by etching. Even more preferentially, it is removed by chemical etching.

In advantageous manner, the etching kinetics of the material of the seed layer 4 are lower than those of the metallic layer 3, which enables etching called selective etching to be performed, This etching kinetics difference is due to the presence of the glassy phase in the material composing the seed layer 4, the metal supplying the seed layer 4 with the electric conduction in particular enabling subsequent formation of the metallic contact by electrochemical deposition. The material of the metallic layer 3 is thus etched, whereas the seed layer 4 is not etched or is only slightly etched. When etching is performed, only the metallic layer 3 will be removed releasing the insulating layer 2.

As represented in FIG. 3, after the metallic layer 3 has been removed, the surface of the cell is formed by the electrically insulating layer 2 through which the seed layer 4 is arranged,

The electric contact 5 is then deposited on the seed layer 4, Preferentially, step iv), i.e. formation of the electric contact 5 on the seed layer 4, is performed by electroless and/or electrolytic deposition.

The seed layer 4 has a resistivity such that it will be possible to deposit an electric contact 5 by electrochemical deposition, or by electroless deposition on the seed layer 4.

Due in particular to its composition, the seed layer 4 has a lower resistivity than that of the electrically insulating layer 2 and a higher resistivity than that of the metallic layer 3.

Preferentially, the material forming the electric contact 5 has a lower resistivity than that of the material forming the seed layer 4. For example purposes, the resistivity of the seed layer 4 is about 1*10⁻⁴ ohm·cm-1*10⁻³ ohm·cm and that of the electric contact 5 formed is about 1*10⁻⁶ ohm·cm.

The electric contact 5 is deposited by electrochemical deposition (ECD). The seed layer 4 thus acts as activation layer, i.e. the seed layer 4 acts as starting or germination layer for formation of the electric contact 5.

The electric contact 5 can in particular be deposited by electrolytic or electroless deposition. Electrolytic deposition is then performed by a wet method without using electric current, and is based on the presence of a reducing agent in solution to reduce metallic ions on the surface of the seed layer 4.

Advantageously, the chemical etching used to remove the metallic layer 3 is selective and there is no notable etching of the electrically insulating oxide layer 2 which enables parasite depositions to be avoided when the electroless deposition is performed.

The depositions may be performed by light-induced plating. The electric contacts 5 obtained in this way are dense and present a resistivity close to that of the bulk metal. Advantageously, they are made at low temperature. The layers of the substrate are thus preserved. In the case of a heterojunction photovoltaic cell, the amorphous layers are not damaged. What is meant by low temperature is a temperature of less than 100° C. For example, this is a temperature of about 25° C. for an electrolytic copper deposition, 40 for an electrolytic silver deposition or 90° C. for an electroless deposition.

As represented in FIGS. 4 to 6, in cross-sectional view along an axis perpendicular to the stack of the photovoltaic cell, the electric contact 5 obtained in this way presents a mushroom shape. What is meant by mushroom shape is that the contact is substantially in the form of a rectangular base and a broader hemispherical head.

The base of the contact 5 is located in the via 9 of the electrically insulating layer 2. Preferentially, the base of the electric contact 5 fills the via 9. The base of the electric contact 5 is in contact with the seed layer 4 forming the bottom of the via 9 and the insulating layer 2 forming the edges of the via 9. The head of the electric contact 5 covers the base of the electric contact 5 and can partially cover the edges of the via 9, i.e. the contact 5 partially covers the electrically insulating layer 2, as represented in FIG. 4.

Preferentially, the base of the electric contact 5, i.e. the width of the seed layer 4, has a width less than 40 μm, preferably less than 20 μm. The width of the head of the electric contact 5 is called “width of the electric contact” and corresponds to the width of the visible part of the electric contact 5. The electric contact 5 has a width of less than 50 μm, and preferably less than 35 μm.

For example, for a seed layer 4 with a width of 20 μm and for an electric contact 5 having a thickness of 7 μm, the width of the electric contact is 35 μm. What is meant by width of the electric contact is the sum of the thicknesses of the base and head of the electric contact 5.

Even narrower lines can be obtained by performing a laser irradiation through a mask. It is thus possible to obtain a high productivity using a laser of large size. In this case, the tracks 4 obtained could have widths of 10 μm and the electric contacts 5 have widths of 25 μm.

The electric contact 5 can for example be made from nickel, silver. copper, cobalt, tin or one of their alloys. According to a preferred embodiment, the electric contact 5 is made from copper or silver in order to have a higher conductivity. Advantageously, the use of copper rather than silver for example enables the production costs of the photovoltaic cell to be reduced. The conductivity of copper (63*10⁵ S·m⁻¹) is substantially higher than that silver (59.6*10⁶ S·m⁻¹).

In the case of use of a copper electric contact 5 and a silicon photovoltaic cell, the presence of the seed layer 4 acts as barrier layer between said electric contact 5 and the silicon of the photovoltaic cell 1, i.e. this layer prevents diffusion of the copper, which has a large propensity to diffuse when heat treatment is performed even at low temperature. The seed layer 4 prevents contamination of the silicon. It is on account of this contamination that it is not common to use copper without a barrier in metallization of a photovoltaic cell.

According to a particular embodiment, the electric contact 5 can be achieved by successive deposition of several metals, advantageously chosen from copper, silver and tin. The metals forming the electric contact 5 are chosen from copper. silver and tin. The combined thickness of the metal films is less than 30 μm, preferentially less than 15 μm. This thickness range enables contacts 5 presenting a low resistivity to be obtained which are at the same time inexpensive as far as the raw material is concerned.

The electric contact 5 is for example made by successive depositions of a silver film, a copper film and then a tin film. The films have for example respective thicknesses of 1 μm, 6 μm and 2 μm, i.e. a total thickness of 9 μm.

Preferentially, the copper film is located between the other metallic films: it is positioned in the core of the electric contact 5.

The electric contact 5 is for example in the form of a comb, i.e. in the form of parallel or substantially parallel lines. The lines are connected to one another at one of their ends by an additional line, perpendicular to the other lines. The electric contact 5 can be composed of a single comb or of several interdigitated combs. to The electric contact 5 can for example be formed by parallel lines having a width comprised between 20 μm and 70 μm, preferably between 20 μm and 45 μm, with a thickness comprised between 5 μm and 30 μm and with a space between lines comprised between 1 mm and 3 mm.

Furthermore, the pattern of the seed layer 4 formed on the surface of the substrate is made according to the geometry of the required electric contact 5.

The different materials used to produce the photovoltaic cells described in the foregoing will be chosen by the person skilled in the art.

In particular, the metallic layer 3 has to be electrically conducting in order to form a third electrically conducting material when said layer merges with the insulating layer 2. Preferably, the metallic layer 3 is a non-transparent layer in order to be able to absorb the laser radiation. Preferentially, the metallic material of layer 3 is silver-based. It can be made from silver and/or from silver oxide. It can also be formed by a silver alloy. Silver, even in oxidized form, is an electrically conducting material. Oxidisation of the silver can take place during the melting step.

The thickness of the metallic layer 3 is preferentially more than 10 nm, and even more preferentially more than 30 nm. The thickness of the metallic layer 3 is this sufficiently large to absorb the energy of the laser, Deposition of the metallic layer can be performed by physical vapor deposition (PVD), which enables a layer to be obtained that adheres well on the underlying layer thereby consuming a minimum of metal.

The electrically insulating layer 2 is an inorganic layer, advantageously made from a silicon oxide base, for example from SiO₂ or doped SiO₂, or it can be formed by a SiN-SiO₂ or SiO₂/MgF₂ multilayer stack.

Preferentially, the metallic layer silver-based and the electrically insulating layer 2 is made from a SiO₂ base.

In particular, the temperature necessary for obtaining the seed layer 4 made from third material will be able to be lowered by using a layer of doped SiO₂. for example by addition of Ca, B or P. An element compatible with the type of doping used in the semiconductor material layer situated on the same surface of the photovoltaic cell will preferably be used.

The electrically insulating layer 2 preferably has a thickness of less than 200 nm, and preferably less than 50 nm, which facilitates softening of said layer and enables it to be made to react over its whole thickness with the metal.

The ratio between the thickness of the electrically conducting metallic layer 3 and the thickness of the electrically insulating layer 2 is furthermore advantageously greater than 10%, and preferably greater than 30%.

Preferentially the electrically insulating layer 2 is made from SiO₂ and the metallic layer is made from silver.

For example, the electrically insulating layer 2 is a layer of SiO₂ with a thickness of 50 nm and the metallic layer is a layer of silver with a thickness of 25 nm, the ratio between the thickness of the metallic layer 3 and the thickness of the electrically insulating, layer 2 being 50%.

Preferentially, the material forming the transparent conductive oxide (TCO) layer 6 is an indium-based compound, for example indium-tin oxide (ITO), indium oxide, indium and tungsten oxide or a zinc-based compound, for example zinc oxide which may be boron-doped ZnO(B). According to another embodiment that is not represented, the oxide layer can also be made from several transparent conductive oxides.

The thickness of the transparent conductive oxide layer 6 is less than 200 nm. The thickness is advantageously comprised between 10 nm and 100 nm, and preferably between 20 nm and 100 nm. The thickness of the transparent conductive oxide layer 6 is for example comprised between 50 nm and 100 nm, which enables at least a part of the thickness of the transparent conductive oxide layer 6 to be preserved when formation of the seed layer 4 takes place, thereby enabling the substrate 1 to be protected.

The transparent conductive oxide layer 6 can be deposited by a plasma-enhanced chemical vapor deposition technique or by physical vapor deposition.

The transparent conductive oxide layer 6 also has particular physico-chemical characteristics, enabling the surface of the doped layer 8 to be passivated. Advantageously, the presence of the transparent conductive oxide layer 6 also enables the optic properties of the cell to be improved. It prevents a too large proportion of the luminous flux which reaches the surface of the cell from being reflected, enabling the current produced by the cell to be increased.

The layers forming the substrate are for example as represented in FIGS. 1 to 6:
a layer of weakly-doped semiconductor material 7 of predefined n- or p-type doping, provided with a front surface and a back surface,
a layer of strongly-doped semiconductor material 8, either with an opposite doping type to that of the layer 7 to form a pin junction, in the case of a standard structure with front-side emitter, or with an identical doping type to that of the layer 7, in the case of a reversed structure with back-side emitter, the second layer being arranged on the front surface of the layer 7.

In the case of the front surface of a reverse-emitter heterojunction cell structure, of identical doping types, the whole thickness of the transparent conductive oxide layer 6 can participate in formation of the third material constituting the seed layer 4 without any risk of short-circuiting in the cell.

In the case of the front surface of a standard-emitter heterojunction cell on the other hand, of opposite doping types, the whole thickness of the transparent conductive oxide layer 6 does not participate in formation of the third material constituting the seed layer 4, At least a part of the thickness of the transparent conductive oxide layer 6 is not modified by the laser irradiation, which enables diffusion of the third material forming the seed layer 4 in the substrate 1 to be limited thereby limiting the risks of short-circuiting. in particular in the case of the front surface of a standard-emitter heterojunction cell structure, of opposite doping types.

What is meant by at least a part of the thickness of the transparent conductive oxide layer 6 is the part of the thickness directly in contact with the substrate 1, and more particularly the strongly-doped semiconductor material layer 8.

The photovoltaic cell obtained by means of the method described in the foregoing comprises a substrate 1 provided with a pin photovoltaic junction and at least one electric contact 5. The electric contact 5 rests directly on a seed layer 4, made from glassy compound doped by a metal, arranged through an electrically insulating material layer 2, said seed layer 4 being electrically connected to the pin photovoltaic junction.

The electrically conducting seed layer 4 is covered by the electric contact 5 made from metallic material. The electric contact 5 has a width of less than 50 μm, and preferably less than 35 μm.

According to a preferred embodiment, a transparent conductive oxide layer 6 is arranged between the substrate 1 and the electrically insulating material layer 2, and the seed layer 4 is electrically connected to the pin junction by means of the transparent conductive oxide layer 6.

In FIGS. 1 to 4, the back surface of the substrate 1 is flat. This back surface can advantageously be covered by an electrode.

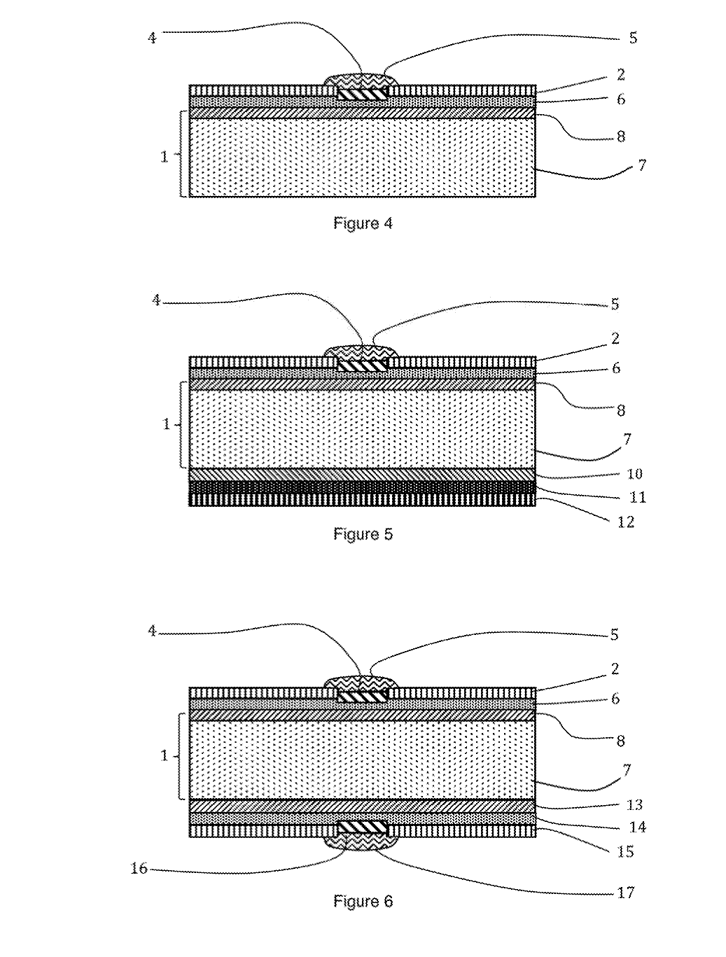

It can however, in other cases, be textured and/or covered by a multilayer stack. For example purposes and as represented in FIG. 5, a photovoltaic cell can comprise in addition to the elements described in the foregoing:
a layer 10 of semiconductor material doped with the opposite doping type to that of the layer 8 placed on the front surface, said layer 10 being deposited on the back surface of the substrate 1, for example made from doped amorphous silicon,
a transparent conductive oxide layer 11 deposited on the third layer 10, for example made from ITO or ZnO.

The photovoltaic cell also comprises a metallic layer 12, for example made from silver.

In FIGS. 1 to 5, the electric contacts 5 are made on one surface of the photovoltaic cell only. When the photovoltaic cell is immersed in the electrolytic bath containing the metal to be deposited in dissolved form, the back surface of the substrate 1 can be protected. Otherwise, a device enabling the electrolyte to be placed in contact with only one surface can be used

According to another embodiment, the photovoltaic cell can also have a structure called bifacial. The method described above is applied on both surfaces of the cell. Irradiation by localised laser beam is performed both on the front surface and on the back surface. The photovoltaic cell is then totally immersed in the electrolyte to form at least one electric contact on the front surface and at least one electric contact on the back surface.

As represented in FIG. 6, the photovoltaic cell obtained then comprises the same stack on the back surface of the substrate 1 as on the front surface, i.e.:
a layer of semiconductor material 13 doped with the opposite doping type to that of the layer 8 placed on the front surface,
a transparent conductive oxide layer 14,
an electrically insulating layer 15, said electrically insulating layer 15 locally comprising a via,
an electrically conducting seed layer 16, made from a metal-charged glassy compound, said seed layer 16 being formed by a mixture of the material of the insulating layer 15 and a metal, said track being electrically connected to the pin junction of the substrate 1 via the transparent conductive oxide layer 14,
an electric contact 17 deposited on said seed layer 16.

The method described above can, be used to fabricate hornojunction photovoltaic cells and heterojunction photovoltaic cells.

In the case of a homojunction photovoltaic cell, weakly doped semiconductor material layer 7 and strongly doped semiconductor material layer 8 of the substrate 1 are made from crystalline semiconductor material. On the other hand, the substrate does not comprise a transparent conductive oxide layer.

In the case of a heterojunction photovoltaic cell, the weakly doped semiconductor material layer 7 of the substrate I is made from crystalline semiconductor material, and the strongly doped semiconductor material layer 8 is made from amorphous semiconductor material.

Preferentially, the semiconductor material used to fabricate the homojunction and heterojunction cells is silicon.

The semiconductor material layers 8, 10 and 13 are preferentially a bilayer stack of intrinsic hydrogenated amorphous silicon that is then doped. The thickness of the stack is comprised between 5 nm and 25 nm.

These layers can be deposited by any type of methods used in the field. The layers can be deposited for example by Plasma-Enhanced Chemical Vapor Deposition (PECVD) at a temperature of less than 300° C..

The layers of the substrate 1 could also be made from one or more other semiconductor materials, such as germanium or a silicon-germanium alloy.

To prevent a too great reflection of the incident light, the surface of the substrate 1, and therefore the surface of the layer 8, can advantageously further present a texturing not shown in the figures), for example in the form of a pyramid.

According to a particular embodiment, after deposition of the electric contact 5, the insulating layer 2 can be removed by any suitable technique.

According to another embodiment, said insulating layer 2 is not removed and will form part of the final cell. The insulating layer 2 is then chosen according to its optic properties, If the insulating layer is left, the latter will advantageously be transparent to solar radiation in order not to reduce the efficiency of the cell. A layer of SiO2 of optic index n=1,4 (k close to 0) presents ideal optic properties, as it is intermediate between the index of air and that of the ITO layer (n=2) on which it can be deposited in the case of heterojunction structures. In the case of homojunction cell structures, a layer of SiO₂ or even a Silk-SiO₂ bilayer can also be interesting.

The laser beam used for this method preferably has a wavelength comprised between 248 nm and 1025 nm, and more particularly between 248 nm and 55 nm. Advantageously, the use of lasers a low pulse time, in the nanosecond or picosecond range, preferably in the range comprised between 15 ps and 300 ns, will enable better control of the energy transmitted to just make the metal melt, The power. i.e. the fluence of the laser is preferably comprised between 0.3 J/cm² and 3 J/cm², preferably between 0.5 J/cm² and 1.5 J/cm².

Various types of laser can be used: either lasers with spots of small size corresponding approximately to the width of the seed layer 4 to be formed, or lasers with spots of large size and by inserting a mask between the beam and the substrate.

For example purposes, the seed layer 4 can be formed, without a mask, with a laser having a wavelength of 355 nm, a pulse time of about a picosecond and a spot size of 20 μm. A power of 0.10 W associated with highspeed scanning, for example 1000 mm/s, will enable the seed layer 4 to be produced in the form of lines with a width of about 28 μm by melting the metal while remaining below the ablation threshold.

A high-frequency laser enabling very short pulses will preferably be used, such as for example a nanosecond laser or preferably a picosecond laser, enabling the heat input to be properly dosed and the reaction with the transparent conductive oxide layer 6 to be limited.

The temperature of the heat treatment, i.e. the temperature applied to the metallic layer 3 during application of the laser beam, is advantageously close to the temperature enabling melting of the metallic layer 3. It is advantageously lower than 1000° C., and even more advantageously comprised between 900° C. and 1000° C. This temperature range, in the case of a metallic layer made from. Ag and an insulating layer made from SiO₂, enables direct melting of the metallic layer, only softening insulating oxide layer and just a surface reaction of the transparent conductive oxide. The reaction takes place for example over a depth of 10 nm to 20 nm of the transparent conductive oxide layer.

Even narrower tracks 4 will be able to be achieved using an excimer laser with a spot of more than 1 cm2 associated with a mask. With a 308 nm excimer laser, 150 ns used with a fluence of 0.7 J/cm2 through a mask provided with 15 μm slits, the seed layer 4 will be produced in the form of segments of seed layer 4 with a width of about 20 μm by melting the metal while remaining below the ablation threshold.

The method for fabricating photovoltaic cells according to the invention enables a low line resistance of the electric contacts to be obtained and, at the same time, enables the passivation properties of the amorphous layer to be preserved, In addition, this method presents the advantage of being robust and easy to implement. Advantageously, all the steps of the method are performed at temperatures of less than 220° C.

1-12. (canceled)

13. A method for fabricating a photovoltaic cell comprising the following successive steps:
i) providing a substrate comprising a p/n photovoltaic junction, successively covered by a transparent conductive oxide layer, a first layer made from electrically insulating material and a second layer made from metallic material,
ii) performing localised heat treatment by laser irradiation under conditions enabling the first layer made from electrically insulating material and the second layer made from metallic material to react locally to form a seed layer, made from a metal-charged glassy compound, said seed layer being electrically connected to the p/n photovoltaic junction by means of the transparent conductive oxide layer,
iii) removing the second layer of metallic material,
iv) forming an electric contact on the seed layer by electrochemical deposition.

14. The method according to claim 13, wherein step iv) is performed by electroless and/or electrolytic deposition.

15. The method according to claim 13, wherein the electric contact has a width of less than 50 μm.

16. The method according to claim 15, wherein the electric contact has a width of less than 35 μm.

17. The method according to claim 13, wherein the electric contact is made from copper.

18. The method according to claim 13, wherein step iv) is performed by successive deposition of several different metals.

19. The method according to claim 18, wherein step iv) is performed by successive deposition of several different metals chosen from copper, silver and tin.

20. The method according to claim 13, wherein the transparent conductive oxide is an indium-based compound.

21. The method according to claim 20, wherein the transparent conductive oxide is chosen from indium and tin oxide, indium oxide, indium and tungsten oxide or a zinc-based compound.

22. The method according to claim 21, wherein the transparent conductive oxide is boron-doped zinc oxide.

23. The method according to claim 13, wherein the second layer made from metallic material is silver-based.

24. The method according to claim 13, wherein the first layer made from electrically insulating material is silicon oxide-based.

25. The method according to claim 13, wherein the ratio between the thickness of the second layer made from metallic material layer and the thickness of the first layer made from electrically insulating material layer is greater than 10%.

26. The method according to claim 25, wherein the ratio between the thickness of the second layer made from metallic material layer and the thickness of the first layer made from electrically insulating material layer is greater than 30%.

27. The method according to claim 13, wherein the first layer made from electrically insulating material layer has a thickness of less than 200 nm.

28. The method according to claim 27, wherein the first layer made from electrically insulating material layer has a thickness of less than 50 nm.

29. A photovoltaic cell comprising a substrate provided with
a p/n photovoltaic junction,
an electrically insulating material layer,
a transparent conductive oxide layer arranged between the substrate and the electrically insulating material layer,
a seed layer made from glassy compound doped by a metal, the seed layer being electrically connected to the p/n junction by means of the transparent conductive oxide layer and
at least one electric contact resting directly on the seed layer and arranged through the electrically insulating material layer, said seed layer being electrically connected to the p/n photovoltaic junction.

30. The cell according to claim 29, wherein the at least one electric contact has a width of less than 50 μm.

31. The cell according to claim 30, wherein the electric contact has a width of less than 35 μm.
